(19) United States
(12) Patent Application Publication
(10) Pub. No.: US 2013/0073235 A1
(43) Pub. Date: Mar. 21, 2013

(54) BATTERY MONITORING DEVICES

(71) Applicants: Nicola REYNTENS, Lede (BE); Johan De Groote, Lede (BE); Hendrik De Vloed, Lede (BE); Bart Verhoeven, Lede (BE)

(72) Inventors: Nicola REYNTENS, Lede (BE); Johan De Groote, Lede (BE); Hendrik De Vloed, Lede (BE); Bart Verhoeven, Lede (BE)

(73) Assignee: Isophi bvba, Lede (BE)

(21) Appl. No.: 13/422,414

(22) Filed: Mar. 16, 2012

Related U.S. Application Data
(60) Provisional application No. 61/453,662, filed on Mar. 17, 2011.

(51) Int. Cl. F16B 2/06; G06F 19/00; G01R 31/36

(52) U.S. Cl. CPC F16B 2/06; G01R 31/36; G06F 19/00
USPC 702/63; 324/426; 24/458

(57) ABSTRACT

Described herein is a battery monitoring device that can easily be mounted on a cable or electrical connection associated with a battery pack for monitoring voltage and/or current of the battery pack. A pair of clamp elements (100, 100′) is assembled around a cable (310) by a sliding engagement of an elongate portion of one clamp element (100, 100′) with slots formed in a body portion (105, 105′) of the other clamp element (100, 100′). Apertures (115, 115′) are provided in the body portions (105, 105′) for housing voltage and/or current sensors.

The present invention relates to battery monitoring devices, and is more particularly, although not exclusively, concerned with current and voltage sensors that are used with measurement clamps.

Battery monitoring devices are known for monitoring the voltage of one or more battery cells. A circuit may be provided that measures the voltage of the battery cell(s) and provides an indication of the remaining power in the battery cell(s), as well the health and state of charge during charging and discharging of the battery cell(s).

Current monitoring techniques can also be used for determining the status of one or more battery cells that are connected to a load or a charger. Current monitoring, combined with voltage and temperature monitoring, provides more information so that it is possible to calculate precisely the status of charge and/or discharge. Without current monitoring, it is not possible to calculate precisely the ampere-hour (Ah) charged or discharged. By using current monitoring, it is very easy to determine with 100% certainty if the battery cell(s) is(are) being charged or discharged, and to calculate the Ah charged and discharged. Therefore, adding current monitoring to battery monitoring devices adds significantly to the quality and preciseness of measurements enabling correct battery management decisions to be made.

However, the devices used for voltage monitoring and current monitoring tend to have different constructions with different mounting techniques.

Existing current-measuring devices utilise either a resistive shunt, placed in series with the conductor or cable being measured, or one Hall sensor integrated into a ferrite ring around the conductor or cable being monitored. The use of ferrite material is to block out external electromagnetic fields.

One of the problems associated with battery monitoring is providing a simple easy construction that can be used for both voltage monitoring devices and current monitoring devices, preferably without interrupting existing connections between the battery cells.

It is therefore an object of the present invention to provide a clamping arrangement in which a sensor arrangement, operating either in a voltage mode or a current mode, can easily be mounted on an electrical connection or cable between a battery pack comprising at least one cell and a load or a charger to which the battery pack is connected.

In accordance with one aspect of the present invention, there is provided a clamp element comprising:—a body portion; an aperture formed in the body portion, the aperture being operable to receive a sensor element; first engagement means formed on one side of the body portion; and second engagement means extending from the other side of the body portion.

In one embodiment, the first engagement means comprises at least one slot formed on the body portion. In this case, the second engagement means comprises an elongate portion having at least one groove formed along at least a part of its length.

The aperture includes alignment slots for receiving the sensor element, and the body portion includes an engagement surface shaped to engage a cable on which the clamp element is to be mounted.

It is preferred that the aperture includes at least one recess for retaining electrical connections associated with the sensor element.

In accordance with another aspect of the present invention, there is provided a clamp assembly comprising first and second clamp elements as described above, wherein the first engagement means of the first clamp element engages the second engagement means of the second clamp element, and the second engagement means of the first clamp element engages the first engagement means of the second clamp element when assembled around a cable.

In accordance with a further aspect of the present invention, there is provided a battery monitoring device comprising a clamp assembly as described above and at least one sensor element.

In this arrangement, at least one sensor element is located within at least one aperture formed in at least one of the first and second clamp elements of the clamp assembly.

The sensor element may comprise a current sensor. In this case, the current sensor comprises a Hall effect sensor with a Hall effect sensor being located in each of the apertures of the first and second clamp elements.

This has the advantage that external magnetic fields can be removed from the current sensing measurements without having to use expensive ferrite material. This is because the two Hall effect sensors are arranged in the clamp assembly so that they are opposed and therefore detect opposite magnetic fields. The signals corresponding to these magnetic fields can be processed so that any external magnetic fields can be cancelled out.

Alternatively, the sensor element may comprise a voltage sensor. In this case, the voltage sensor comprises a conductive plate and a contact element that makes electrical contact with an inner conductor of the cable, the contact element extending through a slot in the engagement surface.

The conductive contact plate may further comprise an electrical connector to which an electrical connection can be made.

In accordance with a further aspect of the present invention, there is provided a battery monitoring system comprising at least one battery monitoring device as described above, a battery monitoring unit connected to each battery monitoring device, the battery monitoring unit comprising processing means for processing signals received from each battery monitoring device.

The battery monitoring unit further comprises a memory for storing the processed signals.

In one embodiment, the battery monitoring system further comprises a gateway having an interface for connecting to the battery monitoring unit. The interface may comprise at least a transmitter provided in each battery monitoring unit and a central receiver located in the gateway. Preferably, the interface comprises a transceiver in the battery monitoring unit and a central transceiver in the gateway.

In broad embodiment the present invention is a monitoring device for currents and voltages intended for but not limited to the use on batteries allowing for a rapid and non-intrusive installation and immune to external magnetic interferences. In addition, other parameters, such as, electrolyte level, battery temperature and time-duration, can also be monitored.

For a better understanding of the present invention, reference will now be made, by way of example only, to the accompanying drawings in which:

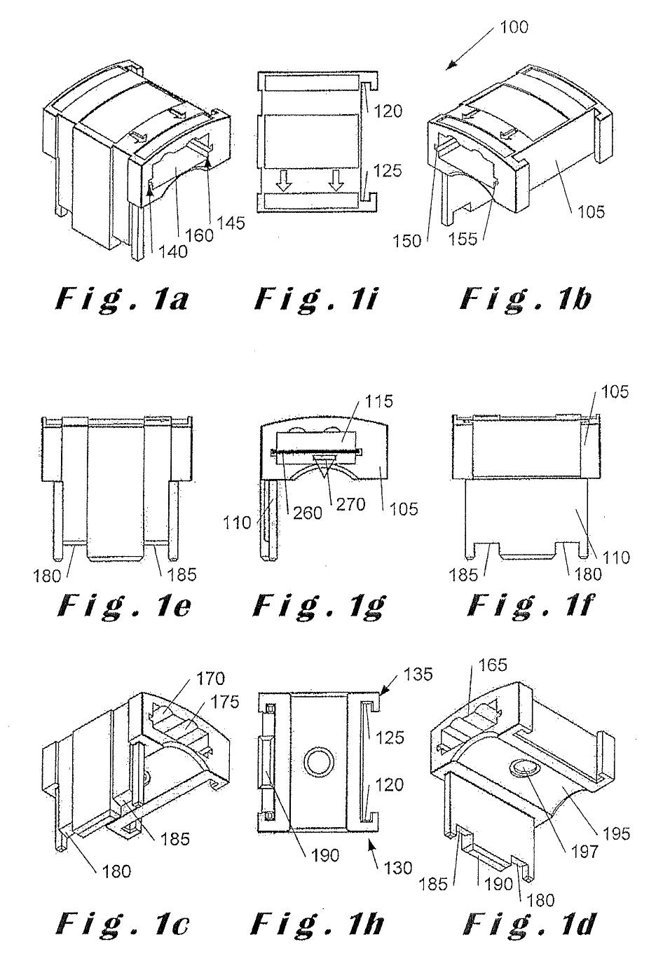

FIGS. 1a to 1i illustrate side perspective views from the top, side perspective views from the bottom, back view, front view, end view, bottom view, and top view respectively of a cable clamp in accordance with the present invention;

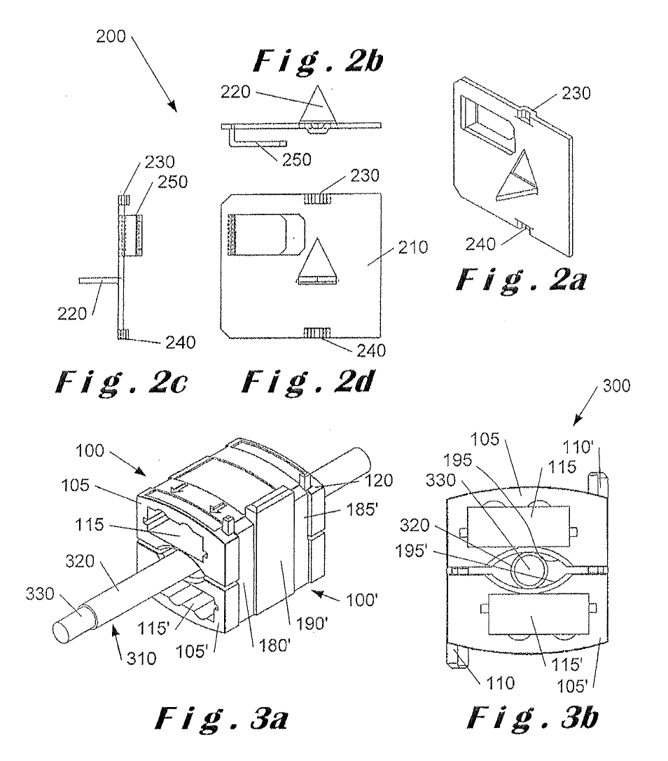

FIGS. 2a to 2d illustrate a perspective view, an end view, a side view, and a top view respectively of a voltage sensor for use with the cable clamp in accordance with the present invention;

FIGS. 3a and 3b illustrate a perspective view and an end view respectively of an assembled voltage sensor arrangement in accordance with the present invention;

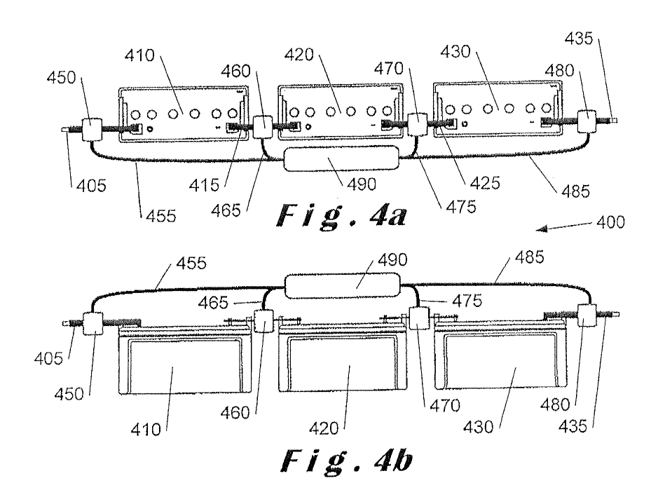

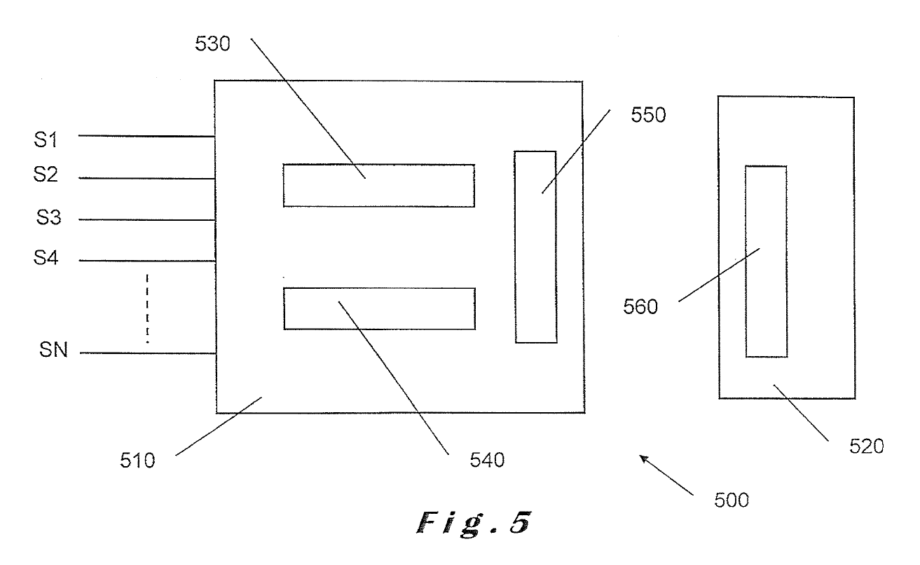

FIGS. 4a and 4b illustrate a plan view and a side view respectively of the battery monitoring arrangement in accordance with the present invention; and

FIG. 5 illustrates a battery monitoring system incorporating the battery monitoring arrangement shown in FIGS. 4a and 4b.

The present invention will be described with respect to particular embodiments and with reference to certain drawings but the invention is not limited thereto. The drawings described are only schematic and are non-limiting. In the drawings, the size of some of the elements may be exaggerated and not drawn on scale for illustrative purposes.

Referring initially to FIGS. 1a to 1i, a cable clamp element 100 is shown that can be connected to an electrical conductor (not shown). The clamp element 100 forms a part of a battery monitoring device in accordance with the present invention as will be described in more detail below.

The cable clamp element 100 comprises a body portion 105 and an elongate portion 110 that connects to and extends substantially perpendicularly to the body portion 105. Ideally, the body portion 105 and the elongate portion 110 are formed as one piece.

The body portion 105 has a substantially rectangular cross-section and defines an aperture 115 that extends through the body portion 105. A sensor 260, as shown in FIG. 1g, and a sensor 200, as shown in FIGS. 2a to 2d, can be inserted into the aperture 115 as will be described in more detail below. The body portion 105 also includes a pair of slots 120, 125 formed as lips located at edges 130, 135 of the body portion 105. The slots 120, 125 extend the depth of the body portion 105.

The term “sensor” as used here with reference to the Figures refers to the current or voltage detecting element as well as any associated electronic components. For example, in current sensing, the sensor comprises a printed circuit board (PCB) that contains a current sensing Hall effect sensor and other associated electronic components.

The aperture 115 includes parallel longitudinal slots 140, 145 formed in respective side walls 150, 155 of the aperture 115. The slots 140, 145 are aligned so that the sensor 260 (FIG. 1g) can be inserted so as to be substantially parallel with bottom wall 160 of the aperture 115 as is shown more clearly in FIG. 1g.

Upper wall 165 of aperture 115 is shaped to provide two longitudinal recesses 170, 175 which accommodate wires (not shown) connected to the sensor 260 (FIG. 1g) as they pass into and out of the aperture 115.

As shown in FIG. 1g, a conical element 270 is connected to the sensor 260 through the bottom wall 160 of the body portion 105. The conical element 270 makes electrical contact with an inner conductor of a cable as will be described in more detail below.

The elongate portion 110 has, at its end remote from the body portion 105, a pair of grooves 180, 185 located on either side of a central protrusion 190. Grooves 180, 185 are designed to engage with slots 120, 125 formed in the body portion 105 so that two clamp elements 100 can be assembled around a cable or other conductor (as shown in FIGS. 3a and 3b) which is connected to a battery to be monitored.

Lower surface 195 of the body portion 105 is shaped to accommodate a cable or other conductor (as shown in FIGS. 3a and 3b) onto which the clamp 100 is to be located. For example, the lower surface 195 comprises a curved surface that ensures that the cable is correctly located within clamp element 100 when assembled on the cable as is described in more detail below.

As shown more clearly in FIGS. 1d and 1h, in one embodiment, a hole 197 is formed in the bottom wall 160 of the body portion 105 into which the conical element 270 can be inserted. The conical element 270 comprises a sharp conductor that pierces the cable 310 (FIGS. 3a and 3b) around which the clamp element 100 is to be attached to provide an electrical connection with a conductor 330 (FIGS. 3a and 3b) within the cable. The conical element 270 has a attachment portion (not shown) that is inserted into the hole 197. The attachment portion is pushed into the hole 197 and may be clicked into place in electrical contact with a conducting portion (not shown) of the sensor. Alternatively, the attachment portion is screwed or clicked directly into an opening (not shown) formed in the sensor 260 forming an electrical contact between the conical element 270 and the sensor 260.

The sensor 260 also includes a substantially rectangular electrical contact member (not shown) to which electrical connections can be made and through which voltage measurements can be made.

When assembled on the cable, an electrical connection is provided between the conductor and the sensor 260 by way of the conical element 270.

It will be appreciated that although a conical element 270 is described, any other suitably shaped sharp protrusion can be provided that has the ability to make electrical contact with the conductor in the cable and the sensor 260.

The cable clamp element 100 can be manufactured using injection moulding techniques and can be moulded from any suitable thermoplastic material, for example, polyethylene, polypropylene or acrylonitrile butadiene styrene (ABS). By using injection moulding techniques and thermoplastic materials, the cable clamp element 100 can be manufactured at low cost.

Turning now to FIGS. 2a to 2d, another voltage sensor 200 is shown that comprises a substantially flat conductive plate 210 having a substantially triangular contact element 220. The contact element 220 is arranged to be perpendicular to the plate 210 so that it can extend away from the plate and through the clamp element 100. Edge portions 230, 240 of the conductive 210 engage with slots 140, 145 formed in the aperture 115 formed in the body portion 105 of the clamp element 100 as will be described in more detail below with reference to FIGS. 3a and 3b. The plate 210 also includes a substantially rectangular electrical contact member 250 to which electrical connections can be made and through which voltage measurements can be made.

Whilst the conductive plate 210, the contact element 220 and the electrical contact member 250 can be made of individual portions and joined together, for example, by welding or brazing, it is preferred that the conductive plate 210, the contact element 220 and the electrical contact member 250 can be made as a single piece. The plate 210 can be stamped out of sheet metal with the contact element 220 and electrical contact member 250 both being formed in the stamping process. The contact element 220 can be bent to be perpendicular to the plate 210 either during the stamping process or afterwards. As an alternative to stamping, the plate 210 can be cut out from the sheet metal using a laser. The conductive plate 210 may be made from any other suitable conductive material.

The substantially triangular contact element 220 forms a sharp protrusion that pierces an isolating sheath of a cable and makes electrical contact with an inner conductor of the cable. The voltage sensor 200 is used for monitoring battery voltages or for extracting electrical power from the conductor. The voltage of other electric sources can also be monitored in this way.

An electrical connection can be made to the electrical contact member 250 before the sensor 200 is inserted into the aperture 115 of the clamp element 100.

In the embodiment of the voltage sensor 200 shown in FIGS. 2a to 2d, an elongate slot (not shown) is provided in bottom wall 160 of the body portion 105 of the clamp element 100, the elongate slot extending from one edge of the body portion 105 to a substantially central position that is located between the two edges of the body portion 105. This elongate slot accommodates the substantially triangular contact element 220 as the sensor 200 is inserted into and retained in the aperture 115 of the clamp element 100. In this embodiment, the sensor 200 is inserted into the clamp element 100 prior to it being located on the cable to be monitored, the contact element 220 extending substantially parallel to the elongate portion 110 as described above with reference to FIGS. 1a to 1i.

The elongate slot can be formed when the clamp element 100 is moulded or it can be added later when the clamp element is to be used for voltage sensing.

Components which have been described previously bear the same reference numerals. Where more than one of a component is shown, the same reference numeral is used followed by a “′”, for example, 100 and 100′.

In FIGS. 3a and 3b, an assembly 300 of two clamp elements 100, 100′, without sensors, are shown. The clamp elements 100, 100′ are connected together around a cable 310 with the grooves 180, 185 of the elongate portion 110 of clamp 100 allowing the central protrusion 190 to engage between slots 120′, 125′ in the body portion 105′ of clamp 100′. Similarly, grooves 180′, 185′ of the elongate portion 110′ allows the engagement of the central protrusion 190′ of clamp 100′ with slots 120, 125 of body portion 105 of clamp 100. The assembly 300 of the two clamps 100, 100′ can be held together by cable ties (not shown) or some other inexpensive fastenings. If cable ties are used, they pass around the assembly 300 in the grooves 180, 185, 180′, 185′ either side the respective central protrusions 190, 190′.

In a voltage sensing device using the sensor 200 as described above with reference to FIGS. 2a to 2d, one sensor 200 is inserted into slots 140, 145 formed in the aperture 115 of clamp 100 before the clamp element 100 is assembled around the cable 310. Alternatively, not shown, the sensor can be inserted in the slot 140′, 145′ formed in the cavity 115′ of clamp 100′. In another embodiment, sensors (not shown) can be inserted into slots 140, 145 in aperture 115 of clamp element 100, 100′ and slots 140′, 145′ of aperture 115′ of clamp element 100′ before assembly on the cable 310.

Regardless of whether one or more sensors (not shown) is inserted in slots 140, 145 and/or 140′, 145′ of respective apertures 115, 115′, the contact element 220 penetrates isolating sheath 320 of cable 310 and makes contact with inner conductor 330. Once the sensor(s) is(are) inserted into the apertures 115 and/or 115′, the two clamp elements 100, 100′ are assembled around the cable 310 with the grooves 180, 185 of the elongate portion 110 of clamp element 100 engaging with slots 120′, 125′ in the body portion 105′ of clamp element 100′ and grooves 180′, 185′ of the elongate portion 110′ of clamp element 100′ engaging with slots 120, 125 of body portion 105 of clamp element 100.

Once assembled, each aperture 115, 115′ is filled with a filler material (not shown) to seal the sensor 200 in place and to prevent ingress of contaminants into the aperture 115, 115′. The filler material can be, for example, a chemically inert hot glue or epoxy resin that hardens to fill the aperture 115, 115′ around each sensor 200, 200′. This is needed when assembly 300 is to be used in an acid environment commonly encountered in the vicinity of lead-acid batteries. It will be appreciated that the filler material also seals any other components associated with the sensor in position, for example, a PCB on which a Hall effect sensor is formed.

As an alternative to voltage sensing as described above with reference to FIGS. 2a to 2d and FIGS. 3a and 3b above, the assembly 300 can be used for current measurements. In this case, two Hall effect sensors can be inserted into respective ones of the slots 140, 145 in aperture 115 and slots 140′, 145′ in aperture 115′ either before or after the clamp elements 100, 100′ have been assembled. As described above, each sensor 200, 200′ is retained in position within respective apertures 115, 115′ by a filler material.

Electricity flowing through the cable to which the assembly 300 is attached produces a magnetic field that varies with the current flowing through the cable. The Hall effect sensors detect the magnetic field and produce an output voltage indicative of the sensed current.

By using two Hall effect sensors, located on either side of the cable, the signals generated by each sensor are combined so that external magnetic fields are cancelled out. This provides a sufficiently accurate measurement of the current carried by the cable. It is to be noted that the provision of the slots 140, 145, 140′, 145′ in respective ones of the apertures 115, 115′ (FIGS. 3a and 3b) provides a way of aligning the sensors with respect to the centre of the cable as the distances between the centre of the cable and each of the Hall effect sensors need to be controllable. In addition, the shape of the lower surfaces 195, 195′ of respective ones of the body portions 105, 105′ provides alignment of the cable 310 within the assembled clamp elements 100, 100′.

In FIGS. 4a and 4b, a battery pack 400 is shown that includes battery monitoring devices in accordance with the present invention. The battery pack 400 comprises three battery cells 410, 420, 430 connected in series by connections 415, 425. Connections 405, 435 connect the battery pack 400 to a load or a charger (not shown). Clamp assemblies 450, 460, 470, 480 in accordance with the present invention are provided on each of the connections 405, 415, 425, 435. Each of the clamp assemblies 450, 460, 470, 480 is connected to a central battery monitoring unit 490 by means of respective connections 455, 465, 475, 485.

The central battery monitoring unit 490 can be located in any suitable position with respect to the battery pack 400 according to space constraints. The clamp assemblies 450, 460, 470, 480 are small enough not to impact on the overall volume of the battery pack 400.

The implementation of the central battery monitoring unit 490 and the clamp assemblies 450, 460, 470, 480 can be achieved on a wide variety of battery packs 400 whilst minimising any difficulties due to the mechanical mounting of the clamp assemblies and mechanical incompatibilities.

In the embodiment shown in FIGS. 4a and 4b, the clamp assemblies 450, 460, 470, 480 provide data relating to battery cell voltage and/or conductor current depending on whether the clamp assembly is configured to measure voltage or to detect current as described above. Additionally, the central battery monitoring unit 490 may be powered through one or more of the clamp assemblies 450, 460, 470, 480.

In addition, the central battery monitoring unit 490 uses voltage and/or current, as well as temperature and/or electrolyte level, information for advance estimating techniques, such as, incoming charge integration, outgoing charge integration and/or impedance measurements, to estimate the charging and/or discharging of the battery pack 400. In addition, the usage, the life expectancy and the ranking of a charged battery in a queue of equal batteries, in order to indicate to a user which battery is charged first, second, . . . , etc. In addition, alarms may be provided to indicate to the user or technical service responsible for the maintenance of the battery packs 410, 420, 430, 440, the current status of each battery etc.

The central battery monitoring unit 490 may be configured to access data relating to predetermined cable types on which the clamp assemblies 450, 460, 470, 480 can be mounted. Such data may be stored in a memory (not shown) that can be accessed by the central battery monitoring unit 490. In one embodiment, the memory forms part of the central battery monitoring unit 490.

Predetermined calibration settings for current and/or voltage measurements can also be stored within the central battery monitoring unit 490 and/or an external memory. These calibration settings can be recalled when required allowing simple installation of the system as described above without the need for further manual calibration by the end user.

The self-centering shape of the surfaces 195, 195′ of the clamp element 100, 100′ described above ensures sufficient mechanical repeatability during their installation on conductions that a precise measurement can be obtained by using only the calibration settings.

A system 500 for use with the battery monitoring devices in accordance with the present invention is shown in FIG. 5. In FIG. 5, the system 500 comprises a central battery monitoring unit 510 and a remote gateway 520. The battery monitoring unit 510 includes a processor 530, a memory 540 and a transceiver 550. Signals S1, S2, S3, S4, . . . , SN from a plurality of clamp assemblies (not shown) and other sensors (also not shown) are input to the battery monitoring unit 510 as shown. The remote gateway 520 includes a transceiver 560.

The processor 530 receives the signals S1, S2, S3, S4, . . . , SN from the clamp assemblies and other sensors (not shown) and processes them to provide current information, voltage information, incoming charge integration, outgoing charge integration and/or impedance measurements relating to the battery pack (also not shown). The processor 530 may also process signals received from other input devices and/or sensors (not shown). This information is formatted and ordered in a desired form and stored in the memory 540 until required by the remote gateway 520 or a computer (not shown) that is also connected to the gateway 520. The computer in this case may be connected to a local access network (LAN) or a wide area network (WAN).

When the data is required, it is transmitted by the transceiver 550 of the battery monitoring unit 510 to the transceiver 560 of the remote gateway 520. If the information is requested by a computer connected to the gateway 520 by a remote LAN or WAN, the gateway 520 transmits the information to the computer over the LAN or WAN once it is received at the gateway 520 from the battery monitoring unit 510.

In the system 500, the data is communicated to the gateway 520 by a wireless connection. The battery monitoring unit 510 may be interrogated by the remote gateway 520 and transmits its data on demand.

By the term “wireless” is intended to include radio transmissions, mobile telecommunications, internet, Bluetooth (registered trade mark of the Bluetooth Special Interested Group) and/or ZigBee (a global standard for providing communication between various devices).

In one embodiment, a plurality of battery packs can be monitored by a plurality of battery monitoring units 510 with all data being transmitted to a central computer or gateway 520 via a wireless connection after initial processing by in the battery monitoring unit or for processing. The gateway 520 may provide automated instructions relating to battery charger status to which the battery packs are connected as well as providing visual cues for personnel managing the proper maintenance and operation of each of the battery packs.

In another embodiment, an industrial computer may be used that communicates wirelessly with the battery monitoring unit 510. In this embodiment, a ZigBee radio module is used for communication with the battery monitor and the gateway.

In a further embodiment, a plurality of battery packs may be located in a charging room and each battery pack has a battery monitoring unit associated with it. A plurality of charging rooms may also be provided which form part of the monitoring system 500. Here, each charging room comprises a gateway 520 that collects data from each battery monitoring unit 510 in the charging room. The collected data is then transmitted to central server (not shown) that is wirelessly connected to each charging room. This central server can be queried by every registered user of the system to generate specific reports containing graphs, lists of every measurement, alarms and events during the service life of every battery cell within the battery packs.

Whilst there is an electrical connection between the current and/or voltage sensors and their associated battery monitoring units in accordance with the present invention, connection between the battery monitoring units and the gateway in the associated charging room may be by wireless ZigBee communication or any other wireless communication system. Wireless communication can also be used for reporting errors detected by the battery monitoring units, for example, by sending automatic e-mails indicating the presence of an error and giving the location from which the error is generated.

In addition, remote web based monitoring may be provided with a central server recording and storing all the data collected from the gateways in each charging room. The data relating to battery monitoring can readily be downloaded from the central server by any internet connected registered user.

The central server also facilitates the connection between an internet connected remote user and the (internet connected) gateway in the battery charging room. The gateway does not need a fixed internet protocol (IP) address and the server keeps track of the changing IP address of each gateway and communicates this IP address to the authorised remote user when requested. In this way, a real-time connection between a gateway, and its battery monitoring units, and a remote LAN or WAN connected user can readily be provided.

As described above with reference to FIGS. 1a to 1i and FIGS. 3a and 3b, only one clamp element need be manufactured as it can be used for both clamp elements that form the assembly 300 around a cable 310. As only one clamp element needs to be made, manufacturing costs are low and provides easy mounting around a cable or other conductor.

The mechanical and compact nature of the assembled cable clamp allows it to be mounted in the most convenient space along a wide variety of current carrying conductors such as a cable or a bus-bar.

As there is no requirement for any hinges in the assembly that is mounted on the cable, lower manufacturing costs and increased reliability when subjected to mechanical stress may be obtained, whilst maintaining easy mounting on a wide variety of cables.

The electrically non-intrusive nature of the current sensing clamp, using Hall effect sensors, and by not making use of more commonly used resistive shunt to sense the current in a conductor contributes to better reliability and safety as well as avoiding any loss of power. In addition, the ability to install the current sensing device with respect to the current carrying conductor with the required accuracy necessary for achieving sufficiently precise current measurements can be provided. Moreover, it is to be noted that the self positioning nature of the current sensing device with respect to the current carrying conductor is necessary for achieving sufficiently precise current measurements.

In addition, the electrical isolation of the current sensing device with respect to the current carrying conductor and any corrosive environment in which the sensor may be located is provided, this is especially important when used on lead-acid batteries where the life expectancy of a standard shunt is not ideal since metal parts are not isolated from the corrosive environment.

When current measurements are to be made, it is advantageous that the current sensing clamp can be assembled on the conductor without having to interrupt the current carrying conductor and without having to solder or weld components to the conductor which contributes to a higher reliability as well as lower time and installation costs.

The electrical isolation of the current sensing device with respect to the current carrying conductor contributes to safety and reliability. In addition, the immunity of the dual Hall effect sensor to external magnetic fields as symmetrical measurements are made on opposite sides of the conductor to cancel out external magnetic fields. Moreover, there is no need for a magnetic field concentrator and hinge mechanism commonly found in Hall effect based current measurement systems. This also contributes to better reliability and lower manufacturing costs.

It is also possible to sense battery voltages without the need to interrupt or temporarily disconnect the existing battery terminal connections. This again contributes to higher reliability and costs associated with installation.

By making use of both current and voltage sensing devices, it is possible to determine the power delivered by a charger to which battery packs that are being monitored. This has the advantage of providing a more accurate battery charging state estimation.

Although the present invention has been described with respect to specific embodiments, it will be appreciated that its scope is not limited to these embodiments, and that other arrangements and configurations are possible.

1. A clamp element comprising:
a body portion;
an aperture formed in the body portion, the aperture being operable to receive a sensor element;
first engagement means formed on one side of the body portion; and
second engagement means extending from the other side of the body portion.

2. The clamp element according to claim 1, wherein the body portion includes an engagement surface shaped to engage a cable on which the clamp element is to be mounted.

3. The clamp element according to claim 1, wherein the first engagement means comprises at least one slot formed on the body portion.

4. The clamp element according to claim 3, wherein the second engagement means comprises an elongate portion having at least one groove formed along at least a part of its length.

5. The clamp element according to claim 1, wherein the aperture includes alignment slots for receiving the sensor element.

6. The clamp element according to claim 1, wherein the aperture includes at least one recess for retaining electrical connections associated with the sensor element.

7. A clamp assembly comprising first and second clamp elements according to claim 1, wherein the first engagement means of the first clamp element engages the second engagement means of the second clamp element, and the second engagement means of the first clamp element engages the first engagement means of the second clamp element when assembled around a cable.

8. A battery monitoring device comprising at least one clamp assembly according to claim 7; and at least one sensor element located within at least one aperture formed in at least one of the first and second clamp elements of the clamp assembly.

9. The battery monitoring device according to claim 8, wherein the sensor element comprises a current sensor.

10. The battery monitoring device according to claim 9, wherein the current sensor comprises a Hall effect sensor, a Hall effect sensor being located in each of the apertures of the first and second clamp elements.

11. The battery monitoring device according to claim 8, wherein the sensor element comprises a voltage sensor.

12. The battery monitoring device according to claim 11, wherein the voltage sensor comprises a conductive plate and a contact portion that makes electrical contact with an inner conductor of the cable, the contact portion extending through a slot in the engagement surface.

13. The battery monitoring device according to claim 12, wherein the contact plate comprises an electrical connector to which an electrical connection can be made.

14. A battery monitoring system comprising at least one battery monitoring device according to claim 8, a battery monitoring unit connected to each battery monitoring device, the battery monitoring unit comprising processing means for processing signals received from each battery monitoring device.

15. The battery monitoring system according to claim 14, wherein the battery monitoring unit further comprises a memory for storing the processed signals.

16. The battery monitoring system according to claim 14, further comprising a gateway having an interface for connecting to the battery monitoring unit.

17. The battery monitoring system according to claim 16, wherein the interface comprises at least a transmitter provided in each battery monitoring unit and a central receiver located in the gateway.

18. The battery monitoring system according to claim 17, wherein the interface comprises a transceiver in the battery monitoring unit and a central transceiver in the gateway.
